(19) United States
(12) Patent Application Publication
(10) Pub. No.: US 2025/0029816 A1
(43) Pub. Date: Jan. 23, 2025

(54) HEATED METAL LID FOR SELECTIVE PECVD

(71) Applicant: Applied Materials, Inc., Santa Clara, CA (US)

(72) Inventors: Douglas Long, Sunnyvale, CA (US); Vinod Kumar Konda Purathe, Bangalore (IN); Dien-Yeh Wu, San Jose, CA (US); Jallepally Ravi, San Ramon, CA (US); Hideaki Goto, Narashino-shi (JP); Manjunatha Koppa, Bengaluru (IN); Hiroyuki Takahama, Katori-shi (JP); Shih Yao Hsu, Santa Clara, CA (US); Sandesh Yadamane Dharmaiah, Bangalore (IN)

(73) Assignee: Applied Materials, Inc., Santa Clara, CA (US)

(21) Appl. No.: 18/773,859

(22) Filed: Jul. 16, 2024

Related U.S. Application Data
(60) Provisional application No. 63/527,972, filed on Jul. 20, 2023.

(51) Int. Cl. H01J 37/32; C23C 16/455

(52) U.S. Cl. CPC H01J 37/32522; C23C 16/45557; C23C 16/45565; H01J 2237/3321

(57) ABSTRACT

Gas distribution assemblies for a semiconductor manufacturing processing chamber comprising a first showerhead with a first flange and a second showerhead with a second flange. A first two-piece RF isolator comprises a first inner RF isolator spaced from a first outer RF isolator. The first inner RF isolator spaced from the first flange of the first showerhead to create a first flow path. A second two-piece RF isolator comprises a second inner RF isolator spaced from a second outer RF isolator. The second RF isolator spaced from the second flange of the second showerhead to create a second flow path. Processing chambers incorporating the gas distribution assemblies, and processing methods using the gas distribution assemblies are also described.

### CROSS-REFERENCE TO RELATED APPLICATIONS

This application claims priority to U.S. Provisional Application No. 63/527,972, filed Jul. 20, 2023, the entire disclosure of which is hereby incorporated by reference herein.

### TECHNICAL FIELD

Embodiments of the disclosure are directed to process chamber lids. In particular, embodiments of the disclosure are directed to process chamber lids that can be heated to elevated temperatures and/or allow for dual plasma capability.

### BACKGROUND

Reliably producing submicron and smaller features is one of the key requirements of very large scale integration (VLSI) and ultra large scale integration (ULSI) of semiconductor devices. However, with the continued miniaturization of circuit technology, the dimensions of the size and pitch of circuit features, such as interconnects, have placed additional demands on processing capabilities. The various semiconductor components (e.g., interconnects, vias, capacitors, transistors) require precise placement of high aspect ratio features. Reliable formation of these components is critical to further increases in device and density.

Additionally, the electronic device industry and the semiconductor industry continue to strive for larger production yields while increasing the uniformity of layers deposited on substrates having increasingly larger surface areas. These same factors in combination with new materials also provide higher integration of circuits per unit area on the substrate.

As the dimensions of devices continue to shrink, so does the gap/space between the devices, increasing the difficulty to physically isolate the devices from one another. Filling in the high aspect ratio trenches/spaces/gaps between devices which are often irregularly shaped with high-quality dielectric materials is becoming an increasing challenge to implementation with existing methods including gap fill, hardmasks and spacer applications.

Remote plasma enhanced chemical vapor deposition (PECVD) of titanium silicide (TiSi) has demonstrated good selectivity on silicon (Si) and silicon germanium (SiGe) surfaces relative to dielectrics like silicon nitride (SiN). However, the PECVD of TiSi suffers from high particle counts due to the condensation of the TiCl_{X} byproducts. To prevent this byproduct condensation, the process chamber lid must be heated to very high temperatures. Additionally, the chemistry involved in the deposition process is highly corrosive so the heating element must be isolated from the process gases. Conventional ceramic heater designs suffer from reliability issues at the temperatures required for deposition as well as contribute to defects formed in the deposited films.

Accordingly, there is a need in the art for process chamber lids that can be heated without creating device defects.

### SUMMARY

One or more embodiments of the disclosure are directed to a gas distribution assembly for a semiconductor manufacturing processing chamber including: a first showerhead connected to a backing plate, the backing plate having a first flange defining an outer edge, the first flange having a first portion extending orthogonally from a back surface of the backing plate and a second portion extending orthogonally outward from the first portion; a second showerhead spaced from the first showerhead, the second showerhead having a second flange having a first portion extending along a plane of the second showerhead, a second portion extending orthogonally from a back of the first portion and a third portion extending orthogonally outward from the second portion; a first two-piece RF isolator including a first inner RF isolator and a first outer RF isolator, the first inner RF isolator spaced a distance from the first outer RF isolator to create a first portion of a first flow path and the first inner RF isolator spaced from the first flange of the first showerhead to create a second portion of the first flow path; and a second two-piece RF isolator including a second inner RF isolator and a second outer RF isolator, the second inner RF isolator spaced a distance from the second outer RF isolator to create a first portion of a second flow path and the second inner RF isolator spaced from the second flange of the second showerhead to create a second portion of the second flow path.

Additional embodiments of the disclosure are directed to a semiconductor manufacturing processing chamber comprising: a chamber body having a bottom wall and at least one sidewall enclosing an inner volume; a gas distribution assembly positioned on a top of the sidewall, the gas distribution assembly including: a first showerhead connected to a backing plate, the backing plate having a first flange defining an outer edge, the first flange having a first portion extending orthogonally from a back surface of the backing plate and a second portion extending orthogonally outward from the first portion; a second showerhead spaced from the first showerhead, the second showerhead having a second flange having a first portion extending along a plane of the second showerhead, a second portion extending orthogonally from a back of the first portion and a third portion extending orthogonally outward from the second portion; a first two-piece RF isolator including a first inner RF isolator and a first outer RF isolator, the first inner RF isolator spaced a distance from the first outer RF isolator to create a first portion of a first flow path and the first inner RF isolator spaced from the first flange of the first showerhead to create a second portion of the first flow path; and a second two-piece RF isolator including a second inner RF isolator and a second outer RF isolator, the second inner RF isolator spaced a distance from the second outer RF isolator to create a first portion of a second flow path and the second inner RF isolator spaced from the second flange of the second showerhead to create a second portion of the second flow path; a pumping ring within the inner volume, the pumping ring positioned below a bottom surface of the second inner RF isolator and a bottom surface of the second outer RF isolator; and a substrate support within the inner volume, the substrate support having a support body on a support shaft, the support body having a support surface spaced a distance from a front surface of the second showerhead to form a process region.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 shows a cross-sectional schematic view of a processing chamber in accordance with one or more embodiments of the disclosure;

FIG. 2 shows an expanded view of a portion of the semiconductor manufacturing processing chamber 100 of FIG. 1;

FIG. 3 illustrates an expanded view of a gas distribution assembly according to one or more embodiments of the disclosure;

FIG. 4 illustrates a portion of the gas distribution assembly shown in FIG. 3;

FIG. 5 illustrates a portion of the gas distribution assembly shown in FIG. 3; and

FIG. 6 illustrates a schematic representation of a semiconductor manufacturing processing chamber according to one or more embodiments of the disclosure illustrating gas flow paths.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

As used herein, “chemical vapor deposition” refers to a process in which a substrate surface is exposed to precursors and/or co-reagents simultaneous or substantially simultaneously. As used herein, “substantially simultaneously” refers to either co-flow or where there is overlap for a majority of exposures of the precursors. Plasma enhanced chemical vapor deposition (PECVD) is widely used to deposit thin films due to cost efficiency and film property versatility. In a PECVD process, for example, a hydrocarbon source, such as a gas-phase hydrocarbon or a vapor of a liquid-phase hydrocarbon that have been entrained in a carrier gas, is introduced into a PECVD chamber. A plasma-initiated gas, typically helium, is also introduced into the chamber. Plasma is then initiated in the chamber to create excited CH-radicals. The excited CH-radicals are chemically bound to the surface of a substrate positioned in the chamber, forming the desired film thereon. Embodiments described herein in reference to a PECVD process can be carried out using any suitable thin film deposition system. Any apparatus description described herein is illustrative and should not be construed or interpreted as limiting the scope of the embodiments described herein.

“Atomic layer deposition” or “cyclical deposition” as used herein refers to a process comprising the sequential exposure of two or more reactive compounds to deposit a layer of material on a substrate surface. “Atomic layer deposition” or “cyclical deposition” as used herein refers to a process comprising the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas (e.g., nitrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas. The gas curtain can be any suitable gas separation arrangement known to the skilled artisan. For example, in some embodiments of a spatial ALD process chamber, a gas curtain is formed by a combination of purge gas ports and vacuum ports to maintain separation between the reactive gases to prevent gas-phase reactions. In some embodiments of a spatial ALD process chamber, separate process stations are configured to form a mini-process environment within each station.

As used in this specification and the appended claims, the terms “reactive compound”, “reactive gas”, “reactive species”, “precursor”, “process gas” and the like are used interchangeably to mean a substance with a species capable of reacting with the substrate surface or material on the substrate surface in a surface reaction (e.g., chemisorption, oxidation, reduction, cycloaddition). The substrate, or portion of the substrate, is exposed sequentially to the two or more reactive compounds which are introduced into a reaction zone of a processing chamber.

One or more embodiments of the disclosure provide CVD lids capable of being heated to 700° C. Some embodiments of the disclosure enable the use of a dual plasma capability. The lid configuration of some embodiments comprises two nickel showerheads and is heated with a metal heater. The metal heater of some embodiments is isolated from the showerhead such that it will not be exposed to the process chemistry.

Metal showerheads are more robust compared to ceramic heaters in conventional processing chambers. The metal heater of some embodiments is configured to heat the metal showerhead to higher temperatures compared to conventional processing chambers. The metal showerhead of some embodiments has dual plasma capability, allowing for a remote plasma. The remote plasma capability can greatly enhance the selectivity of the Ti growth.

Some embodiments of the disclosure replace the ceramic heater currently used with CVD process chambers with a two-piece metal heater. The metal heater of some embodiments is isolated from the process cavity and can be pumped down to vacuum separately. The metal heater of some embodiments mounts onto a metal showerhead. The metal showerhead provides gas distribution as well as acting as an electrode for a remote plasma. In some embodiments, an ion filter (also referred to as the second showerhead) is mounted below the showerhead and acts as an electrode for the direct plasma.

In some embodiments, the lid comprises two showerheads (also referred to as a showerhead and an ion filter), each acting as an electrode for separate plasma cavities. The top showerhead is heated by a metal heater which isolates the heater from the process cavity and chemistry. The metal heater of some embodiments provides heating for the entire lid.

In order to limit heat loss to the exterior environment, the heater of some embodiments can be pumped down to vacuum through a separate vacuum line from the process cavity. In some embodiments, thermal radiation shields are installed above the heater to limit thermal radiation losses. In some embodiments, ceramic isolators are used to electrically isolate the top and bottom showerheads to allow for plasma processing. The ceramic isolators of some embodiments are a two-piece design to limit thermal conduction to the outside environment.

In some embodiments, the showerhead flange on a conventional showerhead is removed for ease of production. In some embodiments, the reflector plate position is adjusted and an injection tube is added for better flow uniformity. In some embodiments, the side purge of the chamber is split into two independent zones. In some embodiments, the ion filter diameter is reduced for improved thermal uniformity.

In some embodiments, the ceramic isolator is split into two pieces. In some embodiments, each ceramic isolator is split into two pieces to elevate the process zone surface temperature.

In some embodiments, there are four purge lines to minimize deposition on the side walls of the chamber and/or purge ring. In some embodiments, there are four channels separated into two mass flow controllers (MFCs), with each MFC controlling two channels.

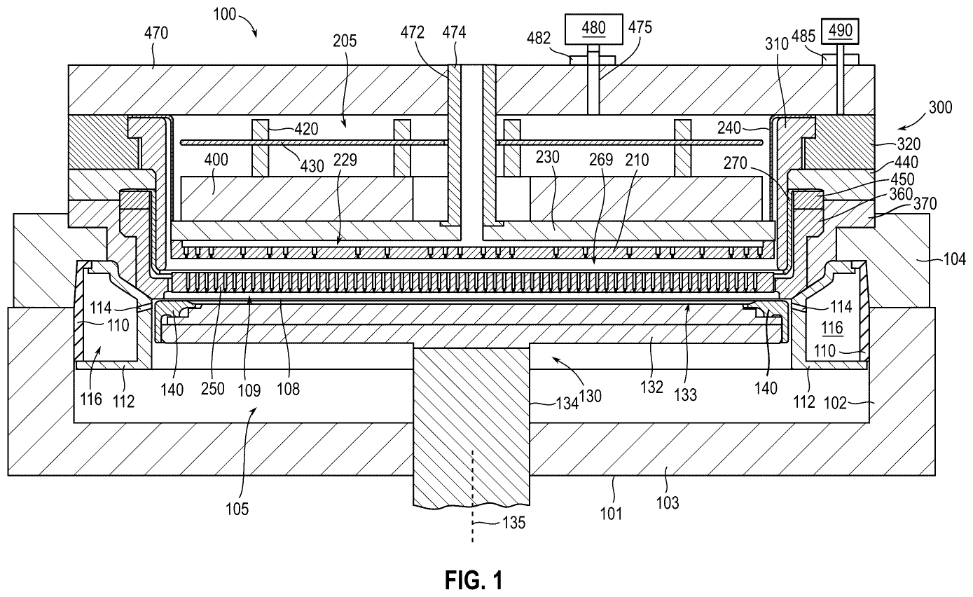

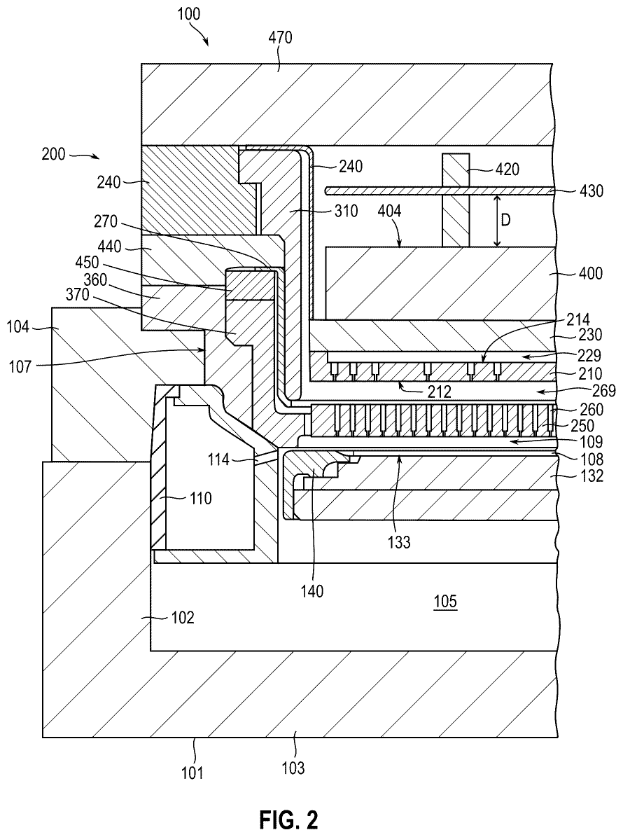

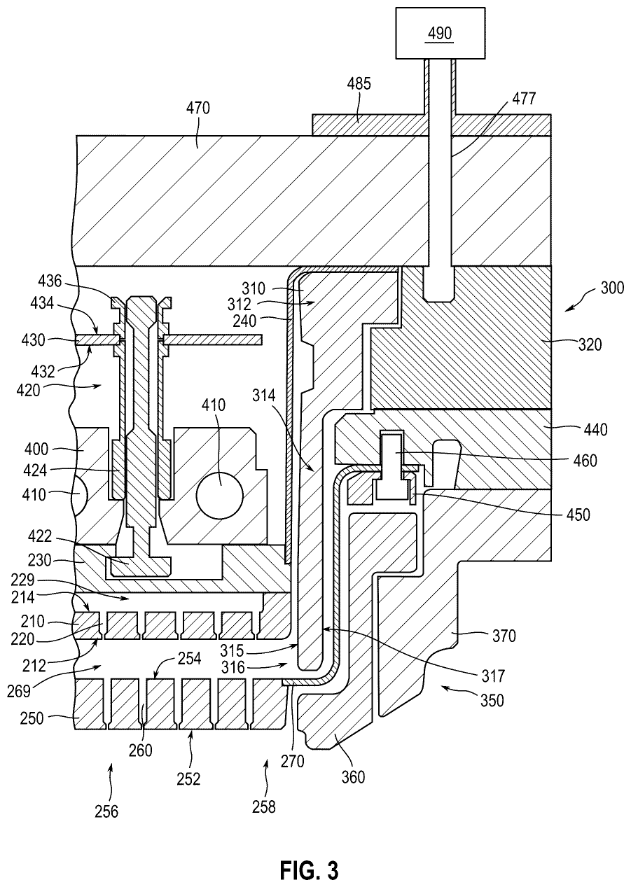

FIG. 1 shows a cross-sectional schematic view of a semiconductor manufacturing processing chamber 100 in accordance with one or more embodiments of the disclosure. FIG. 2 shows an expanded view of a portion of the semiconductor manufacturing processing chamber 100 of FIG. 1. FIG. 3 illustrates an expanded view of a gas distribution assembly 200 according to one or more embodiments of the disclosure. The embodiments illustrated in FIGS. 1 through 3 have two single channel showerheads, dual plasma capability and a detachable metal lid heater.

The semiconductor manufacturing processing chamber 100 comprises a chamber body 101 having sidewalls 102 and a bottom 103 surrounding an interior volume 105. The sidewall 102 and bottom 103 can be integrally formed or separate component connected together by any suitable connection or fastener known to the skilled artisan.

In some embodiments, the chamber body 101 includes a top wall 104. The top wall 104 can be permanently connected to the sidewall 102, or a separate component that is attached to the sidewall 102 by any suitable connection known to the skilled artisan. The top wall 104 illustrated in the Figures has an opening 107 through which a gas distribution assembly 200 is positioned.

The top wall 104 in the Figures is configured to cooperatively interact with one or more components for evacuating process gases from the interior volume 105 of the semiconductor manufacturing processing chamber 100. For example, a pumping liner 110 and pumping ring 112 form an exhaust plenum 116 allowing process gases from the process gap 109 to flow through aperture 114 into the exhaust plenum 116 and out of the semiconductor manufacturing processing chamber 100 through a suitable exhaust system or foreline.

The chamber body 101, in conjunction with the gas distribution assembly 200 encloses the interior volume 105 of the semiconductor manufacturing processing chamber 100. During processing, the interior volume 105 of the semiconductor manufacturing processing chamber 100 is typically maintained at a controlled pressure (usually a low-pressure environment) using one or more gas inlet and one or more exhaust. While exhaust plenum 116 can be used to evacuate gases from the interior volume 105 in addition to the process gap 109, the skilled artisan will recognize that a chamber exhaust (not shown) can be located in any suitable, for example, in the bottom 103 of the chamber body 101. The skilled artisan will be familiar with the general construction of the chamber body 101 and the use of gas inlets and exhaust systems.

The semiconductor manufacturing processing chamber 100 of some embodiments comprises a substrate support 130 within the interior volume 105. The substrate support 130 of some embodiments comprises a support body 132 positioned on a support shaft 134. The support body 132 has a support surface 133 configured to support a semiconductor wafer 108 for processing.

The support shaft 134 of some embodiments is configured to move the support body 132 closer to/further from the gas distribution assembly 200 and/or around a rotational axis 135 of the support shaft 134. During processing, the support surface 133 is spaced from the front surface of the gas distribution assembly 200 to form a process gap 109. While not shown, the skilled artisan will understand that rotational and translational movement of the substrate support 130 can be driven by any suitable mechanism including, but not limited to, motors and actuators.

In some embodiments, the support body 132 includes a thermal element (not shown) configured to heat the semiconductor wafer 108 on the support surface 133. The thermal element can be any suitable heating mechanism known to the skilled artisan. For example, in some embodiments, the thermal element comprises a resistive heating element that is connected to a power supply (not shown) configured to apply power to the thermal element to heat the support body 132. In some embodiments, the support body 132 includes an electrostatic chuck (ESC) (not shown). The skilled artisan will be familiar with the construction of the ESC and the manner in which the ESC is powered and employed.

In some embodiments, as shown in FIGS. 1 and 2, the support body 132 comprises more than one component. For example, the illustrated embodiment has two components connected together by any suitable connection (e.g., brazing or welding). Use of multiple components may allow for easier assembly of the thermal elements or electrostatic chuck components which can be located between and enclosed by the support body components.

In some embodiments, the support body 132 is surrounded by an edge ring 140. The edge ring 140 aids in centering of the semiconductor wafer 108 during processing and also helps to direct gas flows around the edge of the semiconductor wafer 108 to prevent backside deposition or other unwanted reactions on the back of the semiconductor wafer 108 or the support surface 133 of the support body 132.

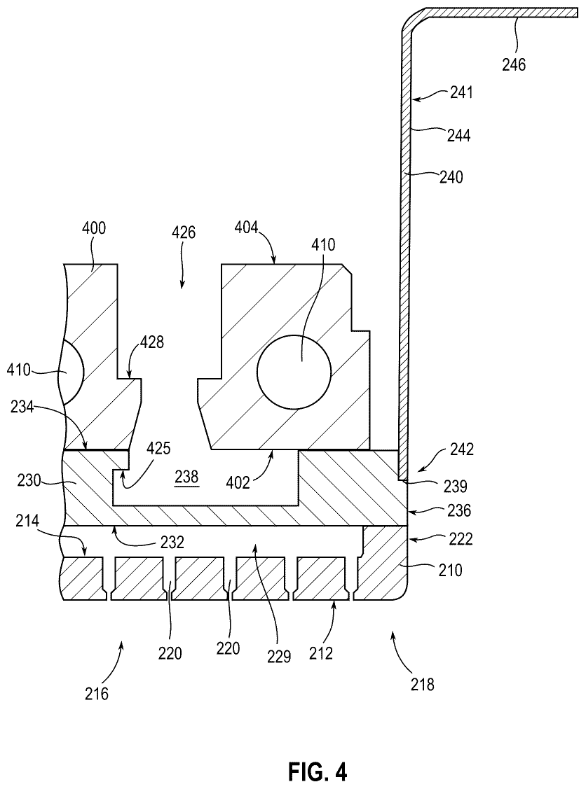

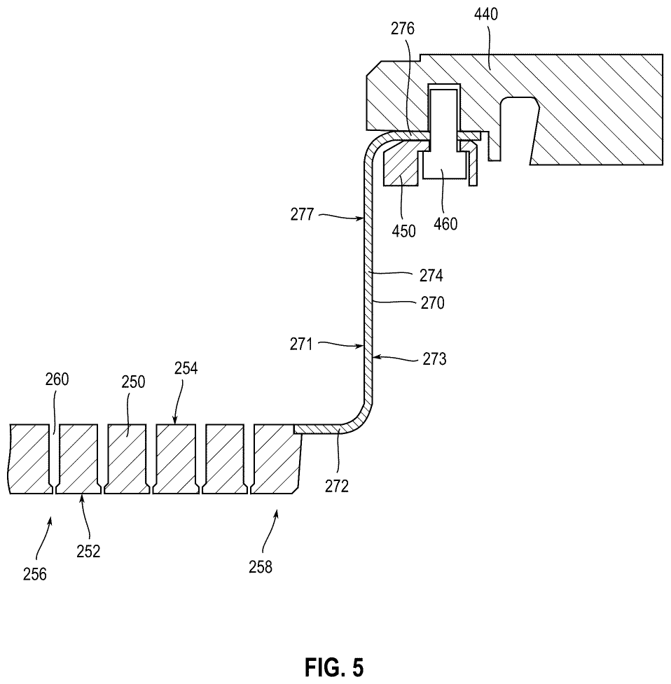

FIGS. 4 and 5 illustrate portions of the gas distribution assembly 200 shown in FIG. 3. With reference to FIGS. 1 through 5, the gas distribution assembly 200 according to one or more embodiments comprises a first showerhead 210 connected to a backing plate 230. The first showerhead 210 can be connected to the backing plate 230 by any suitable connection known to the skilled artisan including, but not limited to, brazing, welding and mechanical fasteners.

The first showerhead 210 has a front surface 212 and a back surface 214 defining the thickness of the first showerhead 210. The first showerhead 210 has an inner region 216 and an outer region 218. The first showerhead 210 is connected to the backing plate 230 at the outer region 218 of the first showerhead 210. The inner region 216 of the first showerhead 210 comprises a plurality of aperture 220 extending through the thickness of the first showerhead 210. The first showerhead 210 has an outer peripheral edge 222 defining the outer boundary of the first showerhead 210.

The backing plate 230 is connected to, or in contact with, the first showerhead 210. The backing plate 230 has a front surface 232 and a back surface 234 defining a thickness of the backing plate 230. The backing plate 230 has an inner portion 231 and an outer portion 233. The outer portion 233 of the backing plate 230 contacts the first showerhead 210 at the outer region 218 of the first showerhead 210. The backing plate 230 has an outer peripheral edge 236 defining the outer boundary of the backing plate 230. In some embodiments, the backing plate 230 includes one or more recess 238 formed in the back surface 234. The one or more recess 238 can be used to connect the backing plate 230 with other components.

The backing plate 230 can be connected to the first showerhead 210 by any suitable connection known to the skilled artisan, or the backing plate 230 can be in contact with the first showerhead 210 with or without an intervening O-ring. For example, the backing plate 230 can be welded to the first showerhead 210. In some embodiments, the backing plate 230 is connected to the first showerhead 210 with a plurality of fasteners (not shown). Suitable fasteners include, but are not limited to, bolts, and can be used with or without O-rings.

In use, a first plenum 229 is formed between the front surface 232 of the backing plate 230 and the back surface 214 of the first showerhead 210. In some embodiments, the first plenum 229 is formed in the inner portion 231 of the backing plate 230 and the inner region 216 of the first showerhead 210. In some embodiments, a recess is formed in one or more of the front surface 232 of the backing plate 230 or the back surface 214 of the first showerhead 210 to create the first plenum 229. Stated differently, when the front surface 232 of the outer portion 233 of the backing plate 230 is in contact with the outer region 218 of the back surface 214 of the first showerhead 210, a plenum 129 is formed in the space between the front surface 232 of the inner portion 231 of the backing plate 230 and the inner region 216 of the back surface 214 of the first showerhead 210.

The backing plate 230 has a center gas inlet 235 extending through the backing plate 230 and in fluid communication with the first plenum 229. The center gas inlet 235 of some embodiments comprises an insulated tube with suitable fittings to connect to the backing plate 230 and to a gas source (not shown). The skilled artisan will be familiar with the types of fitting used for semiconductor manufacturing processing chambers to maintain gas-tight seals.

In some embodiments, the first plenum 229 has a coating to improve chemical compatibility. In some embodiments, the coating covers the entire front surface 232 of the backing plate 230 and the entire back surface 214 of the first showerhead 210, including in the inlet opening (center gas inlet 235) of the backing plate 230 and the plurality of apertures 220 of the first showerhead 210. In some embodiments, the coating is only on the portions of the backing plate 230 and first showerhead 210 that will come into contact with the process gases.

A first flange 240 extends from the outer peripheral edge 236 of the backing plate 230 in a direction away from the front surface 232 of the backing plate 230. The first flange 240 can be connected to the backing plate 230 by any suitable connector known to the skilled artisan, including, but not limited to, brazing and welding. The first flange 240 of some embodiments defines the outer peripheral edge 236 of the backing plate 230. In the illustrated embodiments, the first flange 240 has a bottom end 242 configured to cooperatively interact with a ledge 239 formed in the outer peripheral edge 236 of the backing plate 230. In some embodiments, the bottom end 242 of the first flange 240 extends to the front surface 232 of the backing plate 230 and is connected to the outer peripheral edge 236 of the backing plate 230 and further defines the outer peripheral edge 236 of the backing plate 230. In some embodiments, the first flange 240 is integrally formed with the backing plate 230.

The first flange 240 has a first portion 244 and a second portion 246. The bottom end 242 of the first flange 240 defines the bottom edge of the first portion 244. The first portion 244 of the first flange 240 of some embodiments extends orthogonally from the back surface 234 of the backing plate 230, and the second portion 246 of the first flange 240 of some embodiments extends orthogonally outward from the first portion 244. As used in this manner, the term “orthogonal” has an expanded meaning from the typical definition and means that the angle between the stated components is in the range of 80° to 100°, or in the range of 85° to 95°.

The gas distribution assembly 200 further comprises a second showerhead 250 spaced from the first showerhead 210. The second showerhead 250 has a front surface 252 and a back surface 254 defining the thickness of the second showerhead 250. The second showerhead 250 has an inner region 256 and an outer region 258. The inner region 256 of the second showerhead 250 comprises a plurality of aperture 260 extending through the thickness of the second showerhead 250. The second showerhead 250 has an outer peripheral edge 262 defining the outer boundary of the second showerhead 250.

The second showerhead 250 has a second flange 270 extending therefrom. In some embodiments, the second flange 270 has a first portion 272 extending along a plane of the second showerhead 250 outwardly from the outer peripheral edge 262 of the second showerhead 250, a second portion 274 extending orthogonally from a back of the first portion 272 and a third portion 276 extending orthogonally outward from the second portion 274. In some embodiments, the second flange 270 of the second showerhead 250 has two portions, with one portion extending parallel to the plane of the second showerhead 250 and the other portion extending orthogonally relative to the plane of the second showerhead 250. The parallel and orthogonal portions can be in either order depending on the configuration and connections of the components.

The second showerhead 250 has a back surface 254 that is spaced from the front surface 212 of the first showerhead 210 to form a second plenum 269. The second plenum 269 can be any suitable volume, and the second showerhead 250 can be spaced from the first showerhead 210 by any suitable amount.

In some embodiments, the first showerhead 210 comprises a plurality of apertures 220 extending through a thickness of the first showerhead 210 and the second showerhead 250 comprises a plurality of apertures 260 extending through a thickness of the second showerhead 250, so that a flow of gas can pass through the center gas inlet 235 into the first plenum 229, through the plurality of apertures 220 in the first showerhead 210 into the second plenum 269 and through the plurality of apertures 260 in the second showerhead 250 to flow out of a front surface 252 of the second showerhead 250 and into the process gap 109 between the front surface 252 of the second showerhead 250 and the semiconductor wafer 108, or support surface 133 of the support body 132 of the substrate support 130.

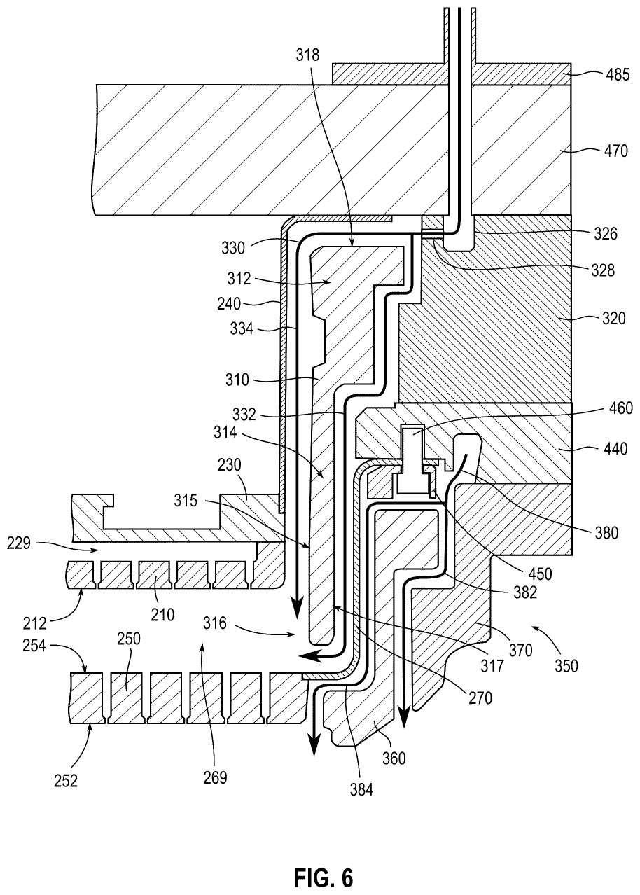

FIG. 6 illustrates a schematic representation of a semiconductor manufacturing processing chamber 100 according to one or more embodiments of the disclosure illustrating gas flow paths. With reference to FIGS. 1-3 and 6, the gas distribution assembly 200 of some embodiments includes a first two-piece RF isolator 300. The first two-piece RF isolator 300 comprises a first inner RF isolator 310 and a first outer RF isolator 320. The first inner RF isolator 310 is spaced a distance from the first outer RF isolator 320 to create a first outer flow path 332 of a first flow path 330. In some embodiments, the first inner RF isolator 310 is spaced from the first flange 240 of the first showerhead 210 to create a first inner flow path 334 of the first flow path 330, as described further below.

The first inner RF isolator 310 has a top portion 312 and a bottom portion 314. The top portion 312 of the first inner RF isolator 310 is defined as the portion of the first inner RF isolator 310 that is closest to and spaced from the first outer RF isolator 320. The bottom portion 314 of the first inner RF isolator 310 extends along the length of the first portion 244 of the first flange 240. In some embodiments, the inside face 315 of the bottom portion 314 is adjacent to and spaced from the outside face of the first portion 244 of the first flange 240. In some embodiments, the bottom end 316 of the bottom portion 314 of the first inner RF isolator 310 extends beyond the first flange 240 so that the bottom end 316 is adjacent to one of the first showerhead 210 or backing plate 230. In some embodiments, the bottom end 316 of the bottom portion 314 of the first inner RF isolator 310 extends below the front surface 212 of the first showerhead 210. In some embodiments, the outside surface 317 of the bottom portion 314 is adjacent to the inside face 277 of the second flange 270. In some embodiments, as shown in FIG. 3, the outside surface 317 of the bottom portion 314 of the first inner RF isolator 310 is adjacent to and spaced a distance from the inside face 277 of the second portion 274 of the second flange 270, and the bottom end 316 of the bottom portion 314 is adjacent to and spaced a distance from the inside face 277 of the first portion 272 of the second flange 270.

In some embodiments, the gas distribution assembly 200 has a second two-piece RF isolator 350. The second two-piece RF isolator 350 comprises a second inner RF isolator 360 and a second outer RF isolator 370. The second inner RF isolator 360 is spaced a distance from the second outer RF isolator 370 to create a first portion of a second flow path 380. In some embodiments, the second inner RF isolator 370 is spaced from the second flange 270 of the second showerhead 250 to create a second portion of the second flow path 380.

The use of ordinals, such as “first” and “second” is intended to help differentiate different components and should not be taken as limiting the disclosure to a specific number of the stated components. For example, in some embodiments, there can be a second flow path, without having a first flow path, as the second flow path is based on the second two-piece RF isolator.

Some embodiments of the gas distribution assembly 200 include a heater block 400. The heater block 400 has a front surface 402 in contact with the back surface 234 of the backing plate 230, and a back surface 404. The heater block 400 comprises at least one heating element 410 within the heater block 400. The at least one heating element 410 can be made of any suitable material and can be any suitable type of heating element known to the skilled artisan. In some embodiments, the at least one heating element 410 comprises a resistive heating element. In some embodiments, the at least one heating element 410 comprises a single coil. In some embodiments, the at least one heating element 410 comprises multiple zones spaced at different distances from a center of the heater block 400. In some embodiments, the at least one heating element 410 comprises a resistive heater which is connected to a power source and/or controller (not shown).

The at least one heating element 410 of some embodiments is configured to heat the backing plate 230 and first showerhead 210 to temperatures greater than typically possible in conventional processing chambers. In some embodiments, the at least one heating element 410 is configured to heat the first showerhead 210 to a temperature up to and including 500° C., 550° C., 600° C., 650° C. or 700° C.

Some embodiments of the gas distribution assembly 200 comprise at least one heater clamp pin 420. As shown in FIGS. 3 and 4, the heater clamp pin 420 extends through the heater block 400 into one or more recess 238 formed in the back surface 234 of the backing plate 230. The at least one heater clamp pin 420 of some embodiments has a flange 422 on the bottom end that engages an upper wall 425 of the one or more recess 238 within the body of the backing plate 230. The at least one heater clamp pin 420 of some embodiments includes a clamp adjuster 424 that allows the at least one heater clamp pin 420 to be tightened or loosened to attach or detach the heater block 400 from the backing plate 230. The heater block 400 of some embodiments, as shown in FIG. 4, has a clamp opening 426 that extends through the body of the heater block 400. In some embodiments, the clamp opening 426 has a clamp surface 428 within the body of the heater block 400. The clamp adjuster 424 of some embodiments engages the clamp surface 428 while the flange 422 of the at least one heater clamp pin 420 engages the upper wall 425 of the one or more recess 238 in the backing plate 230.

One or more embodiments of the gas distribution assembly 200 further comprise a reflector plate 430. The reflector plate 430 has a front surface 432 and a back surface 434. In some embodiments, the reflector plate 430 comprises a reflective material. In some embodiments, the reflector plate 430 is coated with a reflective coating. One or more of the front surface 432 or back surface 434 of the reflector plate 430 has the reflective coating.

The reflector plate 430 of some embodiments is spaced a distance D from a back surface 404 of the heater block 400. The reflector plate 430 is configured to reflect thermal energy from the heater block 400 back toward the first showerhead 210.

The reflector plate 430 of some embodiments is mounted on the at least one heater clamp pin 420. In some embodiments, the at least one heater clamp pin 420 is configured to allow the distance D between the reflector plate 430 and the heater block 400 to be adjusted. In some embodiments, the at least one heater clamp pin 420 comprises a reflector adjustor 436, as shown in FIG. 3. The skilled artisan will understand how the combination of the clamp adjuster 424 and reflector adjustor 436 of the at least one heater clamp pin 420 can be used to control the distance D.

In some embodiments, the gas distribution assembly 200 further comprises an inner RF ground 440 and an outer RF ground 450. In some embodiments, the inner RF ground 440 and outer RF ground 450 comprise conductive materials. In some embodiments, the outer RF ground 450 separates the first outer RF isolator 320 from the second outer RF isolator 370.

In some embodiments, the third portion 276 of the second flange 270 is positioned between the inner RF ground 440 and the outer RF ground 450. The inner RF ground 440 illustrated in the Figures is above the third portion 276 of the second flange 270 and in contact with the inside surface 271 of the second flange 270 and the outer RF ground 450 is below the third portion 276 of the second flange 270 and in contact with the outside surface 273 of the second flange 270. In some embodiments, a fastener 460 connects the inner RF ground 440 and the second flange 270 to the outer RF ground 450 creating an electrical connection between the outer RF ground 450 and the second showerhead 250 through the second flange 270.

While the illustrated second flange 270 has three portions with the third portion being sandwiched between the inner RF ground 440 and outer RF ground 450, the skilled artisan will recognize that this is merely representative of one possible configuration. For example, in some embodiments, the second flange 270 has two portions with a portion of the second portion sandwiched between the inner RF ground 440 and outer RF ground 450.

In some embodiments, the gas distribution assembly 200 includes a chamber lid 470 enclosing a chamber lid inner volume 205. The chamber lid 470 of some embodiments is positioned on the first outer isolator 320. In some embodiments, the first flange 240 is sandwiched between the chamber lid 470 and the first outer RF isolator 320. The chamber lid 470 encloses the reflector plate 430 and heater block 400 in chamber lid inner volume 205. In some embodiments, the chamber lid inner volume 205 is isolated from the ambient environment allowing the chamber lid inner volume 205 pressure and environment to be controlled. In some embodiments, the chamber lid 470 includes an exhaust opening 475 in fluid communication with a vacuum source 480 that is connected to the chamber lid inner volume 205 to maintain a reduced pressure environment in the chamber lid inner volume 205. The skilled artisan will be familiar with suitable vacuum sources and pressure control apparatus that can be employed with the chamber lid 470.

In some embodiments, the chamber lid 470 includes a central inlet opening 472 with an inlet 474 connected thereto. The inlet 474 of some embodiments comprises at least one conduit forming fluid communication between the chamber lid 470 and the first plenum 229 between the first showerhead 210 and the backing plate 230. The skilled artisan will be familiar with suitable gas tight connections (i.e., gas inlet 482) that can be used to allow a process gas to flow through the inlet 474 into the first plenum 229.

In some embodiments, as shown in FIG. 3, the chamber lid 470 further comprises a first gas path opening 477 forming a fluid connection between the chamber lid 470 and the first flow path 330. In some embodiments, a gas inlet 485 is connected to the back surface of the chamber lid 470 and provides a connection point for a gas source 490 to allow a gas to flow through the gas inlet 485 and the chamber lid 470 into the first flow path 330.

FIG. 6 illustrates an expanded view of a portion of the gas distribution assembly 200 showing the various gas flow paths. For ease of understanding the illustrations, O-rings and suitable gas-tight connections are omitted. However, the skilled artisan will understand where and how to include suitable gas-tight connections and O-rings to maintain the various gas flow paths and a controlled environment. The first flow path 330 extends through the chamber lid 470 and splits into a first inner flow path 334 and a first outer flow path 332.

In the illustrated embodiment, the first flow path 330 extends through the chamber lid 470 into a channel 326 in the first outer RF isolator 320 and out a conduit 328 from the channel 326 to the inside surface of the first outer RF isolator 320. The first flow path 330 splits into the first outer flow path 332 and the first inner flow path 334. The first outer flow path 332 extends between the outside surface 317 of the first inner RF isolator 310 and the inside surface of the first outer RF isolator 320, the inside surface of the inner RF ground 440 and the inside surface 271 of the second flange 270 into the second plenum 269. The first inner flow path 334 extends along a top 318 of the first inner RF isolator 310 and into a space between the first inner RF isolator 310 and the outside surface 241 of the first flange 240 into the second plenum 269.

The second flow path 380 extends through the outer RF ground 440 and splits into a second outer flow path 382 and a second inner flow path 384. In one or more embodiments, the second outer flow path 382 is the first portion and/or the second portion of the second flow path 380 and the second inner flow path 384 is the other of the first portion or the second portion of the second flow path 380. The gas flow into the outer RF ground 440 can be by any suitable means known to the skilled artisan. For example, the gas flow into the outer RF ground 440 can be directed from the outside surface of the outer RF ground 440 (or the outside surface of the gas distribution assembly 200). In some embodiments, the gas flow into the second flow path 380 go through the inner RF ground 440 and exits through an opening into the space between the outer RF ground 450, the inner RF ground 440 and the second outer RF isolator 370. The second outer flow path 382 extending between the second outer RF isolator 370 and the second inner RF isolator 360 to a bottom of the gas distribution assembly 200 into the process gap 109 or the edge of the process gap 109. The second inner flow path 384 extends between the second inner RF isolator 360 and the outer surface of the second flange 170 to the bottom of the gas distribution assembly 200 at an edge of the second showerhead 250 and into the process gap 109, or the edge of the process gap 109.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A gas distribution assembly for a semiconductor manufacturing processing chamber comprising:
a first showerhead connected to a backing plate, the backing plate having a first flange defining an outer edge, the first flange having a first portion extending orthogonally from a back surface of the backing plate and a second portion extending orthogonally outward from the first portion;
a second showerhead spaced from the first showerhead, the second showerhead having a second flange having a first portion extending along a plane of the second showerhead, a second portion extending orthogonally from a back of the first portion and a third portion extending orthogonally outward from the second portion;
a first two-piece RF isolator comprising a first inner RF isolator and a first outer RF isolator, the first inner RF isolator spaced a distance from the first outer RF isolator to create a first portion of a first flow path and the first inner RF isolator spaced from the first flange of the first showerhead to create a second portion of the first flow path; and
a second two-piece RF isolator comprising a second inner RF isolator and a second outer RF isolator, the second inner RF isolator spaced a distance from the second outer RF isolator to create a first portion of a second flow path and the second inner RF isolator spaced from the second flange of the second showerhead to create a second portion of the second flow path.

2. The gas distribution assembly of claim 1, wherein a first plenum is formed between a front surface of the backing plate and back surface of the first showerhead.

3. The gas distribution assembly of claim 2, wherein the second showerhead has a back surface spaced from a front surface of the first showerhead to form a second plenum.

4. The gas distribution assembly of claim 3, further comprising a center gas inlet extending through the backing plate in fluid communication with the first plenum.

5. The gas distribution assembly of claim 4, wherein the first showerhead comprises a plurality of apertures extending through a thickness of the first showerhead and the second showerhead comprises a plurality of apertures extending through a thickness of the second showerhead, so that a flow of gas can pass through the center gas inlet into the first plenum, through the plurality of apertures in the first showerhead into the second plenum and through the plurality of apertures in the second showerhead to flow out of a front surface of the second showerhead.

6. The gas distribution assembly of claim 4, further comprising a heater block in contact with the back surface of the backing plate, the heater block comprising at least one heating element within the heater block.

7. The gas distribution assembly of claim 6, further comprising at least one heater clamp pin extending through the heater block into a recess formed in the back surface of the backing plate.

8. The gas distribution assembly of claim 7, wherein the at least one heating element is configured to heat the first showerhead to 600° C.

9. The gas distribution assembly of claim 7, further comprising a reflector plate spaced a distance from a back surface of the heater block, the reflector plate configured to reflect thermal energy from the heater block back toward the first showerhead.

10. The gas distribution assembly of claim 9, wherein the reflector plate is mounted on the at least one heater clamp pin and the at least one heater clamp pin is configured to allow the distance between the reflector plate and the heater block to be adjusted.

11. The gas distribution assembly of claim 10, further comprising a chamber lid positioned on the first outer isolator, the chamber lid enclosing the reflector plate and heater block in chamber lid inner volume.

12. The gas distribution assembly of claim 11, further comprising a vacuum source connected to the chamber lid inner volume to maintain a reduced pressure environment in the chamber lid inner volume.

13. The gas distribution assembly of claim 11, further comprising a gas source connected to the first flow path through the chamber lid.

14. The gas distribution assembly of claim 13, wherein the first flow path extends through the chamber lid and splitting into a first inner flow path and a first outer flow path, the first inner flow path extending between a top of the first inner RF isolator and the first flange into the first plenum, the first outer flow path extending between the first inner RF isolator and the second inner RF isolator, between the first inner RF isolator and the second flange into the second plenum.

15. The gas distribution assembly of claim 1, further comprising an outer RF ground and an inner RF ground comprising a conductive material, the outer RF ground separating the first outer RF isolator and the second outer RF isolator.

16. The gas distribution assembly of claim 15, wherein the third portion of the second flange is between the outer RF ground and the inner RF ground.

17. The gas distribution assembly of claim 16, further comprising a fastener connecting the inner RF ground and the second flange to the outer RF ground creating an electrical connection between the outer RF ground and the second showerhead through the second flange.

18. The gas distribution assembly of claim 16, wherein the second flow path extends through the outer RF ground and splitting into a second outer flow path and a second inner flow path, the second outer flow path extending between the second outer RF isolator and the second inner RF isolator to a bottom of the gas distribution assembly, the second inner flow path extending between the second inner RF isolator and the second flange to the bottom of the gas distribution assembly at an edge of the second showerhead.

19. A semiconductor manufacturing processing chamber comprising:
a chamber body having a bottom wall and at least one sidewall enclosing an inner volume;
the gas distribution assembly of claim 1 positioned on a top of the sidewall;
a pumping ring within the inner volume, the pumping ring positioned below a bottom surface of the second inner RF isolator and a bottom surface of the second outer RF isolator; and
a substrate support within the inner volume, the substrate support having a support body on a support shaft, the support body having a support surface spaced a distance from a front surface of the second showerhead to form a process region.

20. The semiconductor manufacturing processing chamber of claim 19, wherein the gas distribution assembly further comprises a chamber lid positioned on the first outer isolator, the chamber lid enclosing a reflector plate and a heater block in a chamber lid inner volume, and the processing chamber further comprises a remote plasma source in fluid communication with the first plenum through a center gas inlet.
